(19) United States
(12) Patent Application Publication
(10) Pub. No.: US 2005/0218797 A1
(43) Pub. Date: Oct. 6, 2005

(54) Electroluminescent devices comprising two-dimensional array

(76) Inventors: Helmut Bechtel, Roetgen (DE); Dietrich Bertram, Aachen (DE); Harald Glaser, Freiburg (DE)

Correspondence Address: PHILIPS INTELLECTUAL PROPERTY & STANDARDS, P.O. BOX 3001, BRIARCLIFF MANOR, NY, 10510, US

(21) Appl. No.: 10/521,183

(22) PCT Filed: Jul. 8, 2003
(86) PCT No.: PCT/IB03/03029

§ 371 Date: Jan. 14, 2005

(30) Foreign Application Priority Data
Jul. 17, 2002 (DE) 10232238.4

(51) Int. Cl. H05B 33/00; H01L 27/00

(52) U.S. Cl. 313/506

(57) ABSTRACT

The invention relates to an electroluminescent device, which comprises a first set of bands and a second set of bands, which are arranged in such a way, that they form a two-dimensional mesh with points of intersection between the bands of the first set and the bands of the second set. The bands in each case consist of a sequence of layers and at least one set of bands contains a light-emitting substance, which emits light when a voltage is applied. The band structure increases the contact areas between the individual bands and the light is generated more efficiently.

The invention relates to an electroluminescent device, which comprises a first set of bands and a second set of bands, which are arranged in such a way, that they form a two-dimensional mesh with points of intersection between the bands of the first set and the bands of the second set, at least one set of bands containing a light-emitting substance, which emits light when a voltage is applied between the first set of bands and the second set of bands.

Electroluminescent devices are structures, which emit light when an electrical field is applied. When a corresponding voltage, typically a few volts is applied to two opposing electrodes of the electroluminescent device, positive and negative charge carriers are injected, which migrate to an electroluminescent layer where they recombine and in so doing generate light. Known examples of such a device are light-emitting diodes based on GaP or other III-V-semiconductors.

Although these electroluminescent devices are very efficient, they cannot be readily and economically used in large display systems.

A solution to this problem is afforded by organic light-emitting diodes, so-called OLEDs. Organic light-emitting diodes are made up of multiple functional layers. A typical structure of an OLED is described in “Philips Journal of Research, 1998, 51, 467”. A typical structure comprises a layer of ITO (indium tin oxide) as transparent electrode (anode), a conductive polymer layer, an electroluminescent layer, that is to say a layer of a light-emitting material, in particular a light-emitting polymer, and an electrode composed of a metal, preferably a metal with low work function, (cathode). Such a structure is usually applied on a substrate, generally glass. The light generated reaches the viewer through the substrate. An OLED with a light-emitting polymer in the electroluminescent layer is also referred to as a polyLED or PLED.

Such electroluminescent devices can be manufactured not only with a large screen diagonal, but also with a small depth. If a suitable substrate is used, for example a polymer film, it is even possible to obtain flexible electroluminescent devices.

A flexible electroluminescent device based on a polyLED is disclosed, for example, by U.S. Pat. No. 5,962,967. The electroluminescent device has a woven structure composed of two different centro-symmetrical fibers on. Each of these fibers contains an electrically conductive element and at least one of the two fibers has a coating of a light-emitting polymer. If an electrical field is applied to the two electrically conductive elements, the light-emitting polymer emits light at the points of intersection of the two fibers.

The interface or the contact between two layers is crucially important for the efficiency of an OLED. The better the contact, the more efficient the electroluminescent device is. In particular, an electroluminescent device consisting of a fiber which is only composed of one electrically conductive element, and a fiber having a coating of a light-emitting polymer is not very efficient, since two very different materials are in contact with one another.

Another disadvantage with such an electroluminescent device is that the light emission is stimulated only in areas with close contact between the two fibers.

It is therefore an object of the present invention to provide an improved electroluminescent device.

This object is achieved by an electroluminescent device which comprises a first set of bands and a second set of bands, which are arranged in such a way that they form a two-dimensional mesh with points of intersection between the bands of the first set and the bands of the second set, the bands in each case being composed of a sequence of layers and at least one set of bands containing a light-emitting substance, which emits light when a voltage is applied between the first set of bands and the second set of bands.

In contrast to the known centro-symmetrical fibers the bands have a mirror-symmetrical layer structure. The resulting essentially rectangular cross-section of the bands increases the contact area between two different bands.

The advantageous embodiment as claimed in claim 2 produces a close contact between the two bands. This is achieved in that two materials of the same type, that is two organic materials, are in contact with one another. As a result the charge transfer is more efficient and more charge carriers reach the electroluminescent layer. This not only generates more light, but also increases the light emission area.

The advantageously selected organic materials as claimed in claim 3 are either effective light-emitting substances, hole-conducting materials, electron-conducting materials or suitable substrate materials.

The advantageous embodiment of the first set of bands as claimed in claims 4 to 6 and of the second set of bands as claimed in claims 7 to 9 provides bands, which through their increased contact area and close contact together in a mesh permit effective light generation on the basis of electroluminescence.

The advantageous embodiment of the second set of bands as claimed in claims 10 and 11 further improves the emission characteristics of the electroluminescent device, in that it has a color filter and/or a diffusion barrier layer.

The invention will be further described with reference to examples of embodiments shown in the drawings, to which, however, the invention is not restricted. In the drawings

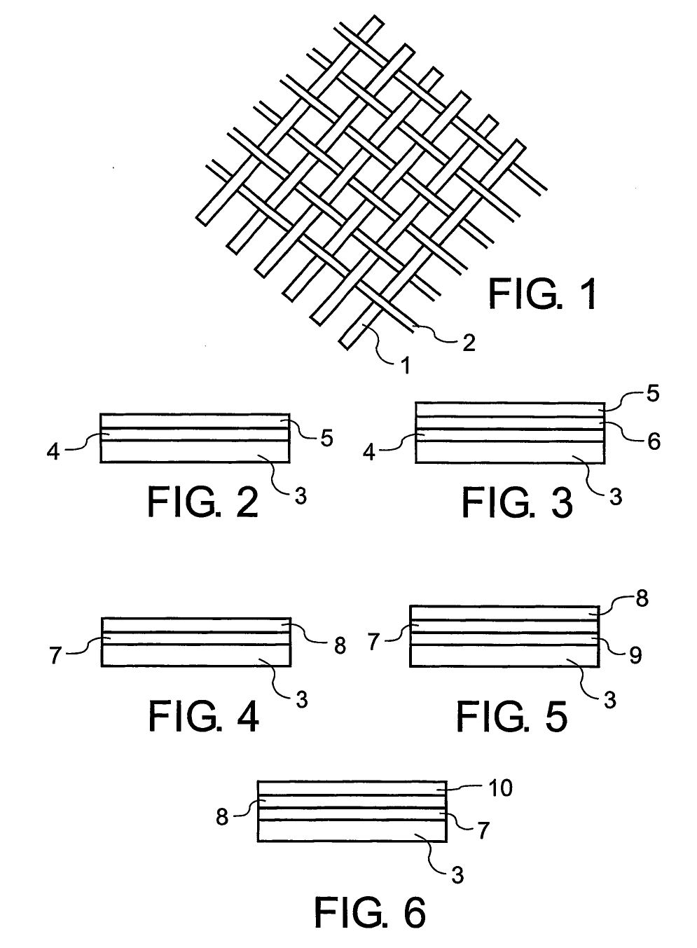

FIG. 1 shows a top view of an electroluminescent device according to the invention,

FIG. 2 shows a cross-section through a cathode band according to the invention,

FIG. 3 a cross-section through another cathode band according to the invention,

FIG. 4 shows a cross-section through an anode band according to the invention,

FIG. 5 shows a cross-section through another anode band according to the invention and

FIG. 6 shows a cross-section through yet another anode band according to the invention.

According to FIG. 1 an electroluminescent device according to the invention has a two-dimensional mesh composed of bands. The bands comprise a first set of bands, which may also be called cathode bands 1, and a second set of bands, which may also be called anode bands 2. As is clear from FIG. 1, the bands are arranged in such a way that a two-dimensional mesh or array of points of intersection is obtained, each cathode band 1 crossing a specific anode band 2 only once and vice-versa. In this mesh, light is generated at each second point of intersection.

Alternatively, a mesh may have other woven patterns so that, for example, a mesh is produced in which each anode band 2 spans three cathode bands 1.

FIG. 2 shows a cross-section through an embodiment of a cathode band 1. A cathode band 1 has a flexible substrate 3, which preferably contains an organic polymer such as polyamide. Adjoining the substrate 3 is a first electrode 4 in the form, for example, of an electrically conductive layer of a metal such as aluminum, copper, silver or gold, an alloy or n-doped silicon. The second electrode 4 advantageously has two or more layers. It is in this case particularly preferable that the second electrode 4 should contain a first layer, which adjoins the substrate 3 and is composed of aluminum, copper, silver or gold and a second layer composed of an alkaline earth metal, such as cesium, calcium or barium, for example. Alternatively, the second layer may contain a layer of biphenyl, which is doped with an alkaline metal, preferably cesium.

In a further possible embodiment the first electrode 4 contains four conductive layers. The first layer, which adjoins the substrate 3, contains aluminum. The second layer contains aluminum and SiO₂ in a molar ratio Al/SiO₂ of 3:1. The third layer, which adjoins the second layer, contains aluminum. The fourth layer contains the alkaline earth metal. By means of this structure of the first electrode 4, the reflection of ambient light is reduced through destructive interference, thereby improving the image contrast of the electroluminescent device.

In a further possible alternative, the first electrode 4 comprises multiple layers, of which one is composed of a material with a high refractive index, preferably ZnS. Such a first electrode 4 has a first layer, which adjoins the substrate 3 and is composed of the material with a high refractive index. Adjoining this first layer is the second layer composed of a metal, especially silver, and adjoining the second layer is the third layer, which contains the alkaline earth metal or alkaline metal-doped biphenyl. This structure makes the first electrode 4 transparent, that is to say transmissive to the light generated in the electroluminescent device.

Adjoining the first electrode 4 is a first organic layer 5, which contains a light-emitting substance. In this embodiment the first organic layer 5 is the electroluminescent layer of the electroluminescent device.

The light-emitting substance may, for example, contain a light-emitting organic polymer such as, for example, poly(p-phenylvinylene) (PPV) or a substituted PPV, such as dialcoxy-substituted PPV, for example. Alternatively, polypyrrole, polythiophene, polyaniline and substituted and/or doped derivatives of these polymers, for example, may also be used as light-emitting substances. Other suitable light-emitting polymers are, for example, poly[2-(6-cyano-6-methylheptyloxy)-1,4-phenylene (CN-PPP), poly[9,9-dihexyl fluorenyl-2,7-diyl], poly[9,9-di-(2-ethylhexyl)-fluorenyl-2,7-diyl] or poly[9,9-dioctyl fluorenyl-2,7-diyl].

Alternatively, light-emitting copolymers such as, for example, poly[9,9′-dioctylfluorenyl-2,7-diyl)-co-(1,4-vinylphenylene)], poly[9,9′-dihexylfluorene)-co-(N,N-di(phenyl)-N,N-di(p-butylphenyl)-1,4-diaminobenzole)], poly[9,9′-dihexylfluorenyl-2,7-diyl)-co-(1,4-benzo-[2, 1′,3]thiadiazole)], poly[9,9′-dihexylfluorenyl-2,7-diyl)-co-(2,5-p-xylol)], poly[9,9′-dioctylfluorenyl-2,7-diyl)-co-(3,5-pyridine)], poly[9,9′-dihexylfluorenyl-2,7-diyl)-co-(9,9′-{5-pentenyl}-fluorenyl-2,7-diyl)] or poly[9,9′-dioctylfluorenyl-2,7-diyl)-co-(6,6′-{2,2′-bipyridine})] may also be used as light-emitting substance in the first organic layer 5.

Other suitable light-emitting substances which may be present in the first organic layer 5 are light-emitting oligomers such as, for example, 4,4′-bis(9-ethyl-3-carbazovinylene)-1,1′biphenyl, 9,10-di[(9-ethyl-3-carbazoyl)-vinylenyl]-anthracene, 4,4′-bis(diphenylvinylenyl)-biphenyl or 1,4-bis(9-ethyl-carbazovinylene-2-methoxy-5-(2-ethylhexyloxy)-benzole.

Alternatively the organic layer 5 may contain, as light-emitting substance, a metal complex with at least one organic ligand such as, for example, aluminum oxinate (Alq₃), bis-(2-methyl-8-chinolinolato)-4-(phenyl-phenolato)-aluminum-(III) (BAlq), tris(2-phenylpyridine)iridium (Ir(Ppy)₃), iridium(III)bis(2-(4,6-difluorophenyl)-pyridinato-N,C^{2′})piccolinate (FIrpic), europium(III)-complexes such as, for example, tris-(benzoylacetonato)mono(1,10-phenthroline)-europium or tris-(benzoylacetonato)mono(5-amino-1,10-phenanthroline)-europium, borates such as lithiumtetra(8-hydroxychinolinato)-borate or lithiumtetra(2-methyl-8-hydroxychinolinato)-borate and zinc complexes such as bis(8-hydroxychinolinato)-zinc or bis(2-methyl-8-hydroxychinolinato)-zinc. It is also possible for the organic layer 5 to contain multiple, preferably three, metal complexes, which emit light of different colors. In this embodiment the organic layer 5 may contain, for example, tris-(benzoylacetonato)mono(5-amino-1,10-phenanthroline)-europium as red-emitting metal complex, Alq₃ as green-emitting metal complex and bis(2-methyl-8-hydroxychinolinato)-zinc as blue-emitting metal complex, and emit white light.

FIG. 3 shows a further embodiment of a cathode band 1. In this embodiment two organic layers 5, 6 are applied on the first electrode 4. In this embodiment the first organic layer 5 functions as electron-conducting layer and contains an electron-conducting material such as, for example, a conductive polymer, a conductive oligomer, a metal complex or a heterocycle. The materials may possibly have substituents and/or dopings. A suitable material may comprise an oxadiazole, an oxazole, an isoxazole, a thiazole, an isothiazole, a thiadiazole, 1,2,3 triazole, a 1,3,5 triazine, chinoxaline, an oligopyrrole, a polypyrrole, a phenylenevinylene oligomer, a phenylenvinylene polymer, a vinylcarbazole oligomer, a vinylcarbazole polymer, a fluorene-oligomer, a fluorine polymer, phenylacetylene oligomer, a phenylacetylene polymer, a phenylene oligomer, a phenylene polymer, an oligothiophene, a polythiophene, a polyacetylene or oligoacetylene. A suitable electron-conducting material is, for example, 2-biphenyl-5-(4-tert-butylphenyl)-3,4-oxadiazole (PBD). According to their electron-conducting characteristic, these materials also prevent the transfer of holes through the first organic layer 5 towards the cathode.

In this embodiment the second organic layer 6 functions as electroluminescent layer and contains the light-emitting substance.

FIG. 4 shows a cross-section through an embodiment of an anode band 2. An anode band 2 has a flexible substrate 3, which preferably contains an organic polymer such as polyamide. Adjoining the substrate 3 is a second electrode 7, preferably in the form of a transparent, electrically conductive layer of ITO. Adjoining the second electrode 7 is a third organic layer 8. The third organic layer 8 functions as hole-conducting layer and contains, for example, a conductive polymer, a conductive oligomer or an amine. The materials may possibly have substituents and/or dopings. A suitable material may comprise a tertiary amine, a tertiary aromatic amine, a polymer containing arylamine, an oligothiophene, a polythiophene, an oligopyrrole, a polypyrrole, an oligophenylene vinylene, a phenylene vinylene polymer, a vinylcarbazole oligomer, a vinylcarbazole polymer, a fluorine oligomer, a fluorine polymer, a phenylene acetylene oligomer, a phenylene acetylene polymer, an oligophenylene, a polyphenylene, an acetylene oligomer, a polyacetylene, a phthalocyanine or a porphyrin. Polyethylene dioxythiophene (PDOT), N,N′-bis(3-methylphenyl)-N,N′-bis(phenyl)benzidine (TPD), 4,4′-bis(carbazole-9-yl)biphenyl (CBP) or N,N′-di-[(1-naphthyl)-N,N′-diphenyl]-(1,1′-biphenyl)-4,4′-diamine (α-NPD) are preferably used as hole-conducting materials. According to its hole-conducting characteristic the third organic layer 8 prevents the migration of electrons through the third organic layer 8 towards the anode. In an alternative embodiment the second electrode 7 may contain a hole-conducting material. In order to increase the conductivity, the second electrode 7 may contain metal filaments in addition to the hole-conducting material.

FIG. 5 shows a cross-section through a further anode band 2 according to the invention. In this embodiment an additional layer 9 is situated between the substrate 3 and the second electrode 7. This additional layer 9 may contain a pigment, for example, and thereby function as color filter. Alternatively, an additional layer 9 of SiO₂ may be situated between the substrate 3 and the second electrode 7. This additional layer 9 of SiO₂ functions as diffusion barrier layer.

In principle it is possible for the anode bands 2, rather than the cathode bands 1, to contain the light-emitting substance. In this embodiment the cathode bands have a structure according to FIG. 2 and the first organic layer 5 contains an electron-conducting material. The anode bands 2 may have a structure according to FIG. 6. In this embodiment the anode band 2 has a substrate 3, a second electrode 7, a third organic layer 8 and a fourth organic layer 10, which adjoins the third organic layer 8. In this embodiment the third organic layer 8 contains a hole-conducting material and the fourth organic layer 10 contains the light-emitting substance. Alternatively, the additional layer 9 may also be situated between the substrate 3 and the second electrode 7. It is also possible for the third organic layer 8 to contain the light-emitting substance and the fourth organic layer 10 an electron-conducting material. Alternatively, further organic layers may be applied on the fourth organic layer.

In order to manufacture an electroluminescent device the cathode bands 1 and the anode bands 2 are first produced. In order to produce a cathode band 1 the corresponding materials for the first electrode 4 and the first and any second organic layer 5,6 are first deposited in the corresponding order on an extensive substrate 3. The layer structure obtained is then cut into strips, preferably with a width of between 200 and 500 μm, thus obtaining the cathode bands 1.

The anode bands 2 are produced in the same way, by depositing the corresponding materials for the second electrode 7, the third organic layer 8 and any additional layer 9 and the fourth organic layer 10 in the corresponding order on an extensive substrate 3. The layer structure obtained is then cut into strips, preferably with a width of between 200 and 500 μm, thus obtaining the anode bands 2.

The width of the cathode bands 1 and the anode bands 2 depends on the desired number of lines and columns in the finished electroluminescent device. The width of the cathode bands 1 may be equal to the width of the anode bands 2, but it may also be greater or smaller. The cross-section of the bands is arbitrary, but by virtue of the layered structure of the bands is preferably rectangular, rectangular with rounded edges or trapezoidal.

From the cathode bands 1 and the anode bands 2 an electroluminescent device is woven, using either the cathode bands 1 or the anode bands 2 as weft thread and the other band as warp thread. At the same time, different cathode bands 1 or anode bands 2 may also be used as warp thread or weft thread in an electroluminescent device.

In order to stabilize the two-dimensional mesh obtained, it may be laid between two glass plates. The glass plates are pressed together at temperatures of approximately 80° C., in order to produce a close contact between the cathode bands 1 and anode bands 2. The glass plates are then sealed gas-tight with an adhesive. The adhesive may be thermosetting, for example, or be set by irradiation with UV light.

Alternatively, the two-dimensional mesh may be laminated between two films, for example polycarbonate films.

Furthermore, a circular polarizer, which absorbs incident ambient light and thus increases the contrast, may be introduced into the laminate of two-dimensional mesh and glass or polycarbonate film.

In principle it is also possible for the substrate 3 to be a metal foil, of aluminum, for example, thereby functioning not only as substrate but also as an electrode.

Embodiments of the invention representing feasible means of implementation will be explained below by way of example.

### Example of Embodiment 1

Cathode bands 1 were produced by depositing a 200 nm thick layer of aluminum and a 5 nm thick layer of barium as first electrode 4 on a polyamide film as substrate 3. An 80 nm thick first organic layer 5 of PPV was deposited on the first electrode 4. The coated polyamide film was then cut into 300 μm wide strips.

Anode bands 2 were also produced by depositing a 100 nm thick SiO₂-layer as additional layer 9 on a polyamide film as substrate 3. A 150 nm thick second electrode 7 of ITO was deposited on the additional layer 9. A 200 nm thick third organic layer 8 of PDOT was applied to the second electrode 7. The coated polyamide film obtained was cut into 400 μm wide strips.

From the cathode bands 1 and the anode bands 2 a two-dimensional mesh according to FIG. 1 was produced using the cathode bands 1 as warp thread and the anode bands 2 as weft thread. The mesh obtained was laid between two contra-rotating rollers and compressed at a pressure in excess of 100 N. The two-dimensional mesh was then laminated between two polycarbonate films and provided with electrical connections, so that a flexible electroluminescent device was obtained, which emitted orange-colored light at each second point of intersection.

### Example of Embodiment 2

Cathode bands 1 were produced by depositing a 200 nm thick layer of aluminum and a 5 nm thick layer of barium as first electrode 4 on a polyamide film as substrate 3. A 150 nm thick first organic layer 5 of polythiophene was deposited on the first electrode 4. The coated polyamide film was then cut into 200 μm wide strips.

Anode bands 2 were also produced by depositing a 100 nm thick SiO₂-layer as additional layer 9 on a polyamide film as substrate 3. A 150 nm thick second electrode 7 of ITO was deposited on the additional layer 9. A 200 nm thick third organic layer 8 of PDOT was deposited on the second electrode 7. An 80 nm thick, fourth organic layer 10 of PPV was deposited on the third organic layer 8.

From the cathode bands 1 and the anode bands 2 a two-dimensional mesh according to FIG. 1 was produced using the cathode bands 1 as weft thread and the anode bands 2 as warp thread. The two-dimensional mesh obtained was provided with electrical connections and placed between two 1 mm thick glass plates, which were then pressed together at temperatures of 80° C. and sealed gas-tight by means of an adhesive, which was set by irradiation with UV light. An electroluminescent device was obtained which emitted orange-colored light at each second point of intersection.

### Example of Embodiment 3

Cathode bands 1 were produced by depositing a first electrode 4 comprising three layers on a polyamide film as substrate 3. The first layer, which adjoined the substrate 3, contained a 20 nm thick layer of ZnS, the second layer contained a 20 nm thick layer of Ag and the third layer contained a 10 nm thick layer of biphenyl, which was doped with cesium. A first organic layer 5 of Alq₃ was applied to the first electrode 4. The layer thickness of the first organic layer 5, which functioned as electron-conducting layer, was 80 nm. The coated polyamide film was then cut into 200 μm wide strips.

Anode bands 2 were also produced by depositing a second electrode 7 comprising a 35 nm thick layer of α-NPD on a polyamide film as substrate 3. An 80 nm thick third organic layer 8 with the blue light-emitting substance 4,4′-bis(2,2-diphenyl-ethene-1-yl)-biphenyl (DPVBi) was applied on the second electrode 7. A 50 nm thick fourth organic layer of 2-biphenyl-5-(4-tert-butylphenyl)-3,4-oxadiazole as electron-conducting and hole-blocking layer was applied to the third organic layer 8. The coated polyamide film was then cut into 250 μm wide strips.

From the cathode bands 1 and the anode bands 2 a two-dimensional mesh according to FIG. 1 was produced using the cathode bands 1 as weft thread and the anode bands 2 as warp thread. The two-dimensional mesh obtained was provided with electrical connections and placed between two 1 mm thick glass plates, which were then pressed together at temperatures of 80° C. and sealed gas-tight by means of a thermosetting adhesive. An electroluminescent device was obtained which emitted blue-colored light at each second point of intersection.

### Example of Embodiment 4

Three different cathode bands 1 were produced, which each contained a light-emitting substance, which emitted either red, green or blue light.

A red-emitting cathode band 1R had a polyamide substrate 3, on which a first electrode 4 composed of a 100 nm thick aluminum layer and a 10 nm thick layer of cesium-doped biphenyl, was applied. Adjoining the first electrode 4 was an 80 nm thick first organic layer 5, which contained tris-(benzoylacetonato)-mono(5-amino-1,10-phenanthroline)-europium. The width of the red-emitting cathode band 1R was 300 μm.

A green-emitting cathode band 1G had a polyamide substrate 3, on which a first electrode 4 composed of a 100 μm thick aluminum-layer and a 10 nm thick layer of cesium-doped biphenyl was applied. Adjoining the first electrode 4 was a 75 nm thick first organic layer 5, which contained Alq₃. The width of the green-emitting cathode band 1G was 100 μm.

A blue-emitting cathode band 1B had a polyamide substrate 3, on which a first electrode 4 composed of a 100 nm thick aluminum layer and a 10 nm thick layer of cesium-doped biphenyl was applied. Adjoining the first electrode 4 was a 90 nm thick first organic layer 5, which contained lithiumtetra(2-methyl-8-hydroxychinolinato) borate. The width of the blue-emitting cathode band 1B was 200 μm.

Anode bands 2 were also produced by depositing a second electrode 7 composed of a 35 nm thick layer of α-NPD on a polyamide film as substrate 3. An 80 nm thick third organic layer 8 of 2-biphenyl-5-(4-tert.-butylphenyl)-3,4-oxadiazole (PBD) as hole-conducting layer was applied on the second electrode 7. The coated polyamide film was then cut into 600 μm wide strips.

From the three different cathode bands 1 and the anode bands 2 a two-dimensional mesh according to FIG. 1 was produced using the three cathode bands 1 alternately, that is to say 1R, 1G, 1B, 1R, 1G, 1B, . . . as warp thread and the anode bands 2 as weft thread. The two-dimensional mesh obtained was provided with electrical connections and placed between two 1 mm thick glass plates, which were then pressed together at temperatures of 80 C and sealed gas-tight by means of a thermosetting adhesive. A full-color, electroluminescent device was obtained.

### Example of Embodiment 5

A full-color, electroluminescent device similar to example of embodiment 4 was produced, with the difference that light-emitting polymers were used instead of the light-emitting metal complexes in the respective organic layer 5 of the cathode bands 1R, 1G 1B. A red-emitting cathode band 1R had an 80 nm thick layer of poly[{9-ethyl-3,6-bis(2-cyanovinylene)carbazolylene)}alt-co-[2-methoxy-5-(2-ethylhexyloxy)-1,4-phenylene}]. A green-emitting cathode band 1G had a 75 nm thick layer of poly[/9,9-dioctyl-2,7-divinylene-fluorenylene}-alt-co-{2-methoxy-5-(2-ethylhexyloxy)-1,4-phenylene}]. A blue-emitting cathode band 1B had a 90 nm thick layer of poly[9,9-dihexylfluorenyl-2,7-diyl].

### Example of Embodiment 6

Cathode bands 1 were produced by depositing a 200 nm thick layer of aluminum and a 5 nm thick layer of cesium-doped biphenyl as first electrode 4 on a polyamide film as substrate 3. A 90 nm thick first organic layer 5 of tris-(benzoylacetonato)-mono(5-amino-1,10-phenanthroline)-europium, Alq₃ and lithiumtetra(2-methyl-8-hydroxychinolinato)-borate in a ratio of 3:1:2 was applied to the first electrode 4. The coated polyamide film was then cut into 500 μm wide strips.

Three different anode bands 2 were produced, the anode bands 2 each having a red, blue or green pigment.

An anode band 2R with a red pigment had polyamide as substrate 3, on which there was a 20 nm thick additional layer 9 of C.I. pigment red 177. The second electrode 7 comprising a 130 nm thick layer of ITO was applied on the additional layer 9. On the second electrode 7 there was the 70 nm thick, third organic layer 8 of TPD.

An anode band 2G with a green pigment had a similar structure with the difference that the additional layer 9 contained C.I. pigment green 36.

An anode band 2B with a blue pigment had a similar structure with the difference that the additional layer 9 contained C.I. pigment blue 209.

The additional layer 9 functioned as color filter in the anode bands 2R, 2G, 2B.

The width of the anode band 2R with red color filter was 250 μm, the width of an anode band 2G with green color filter was 100 μm and the width of an anode band 2B with blue color filter was 150 μm.

From the cathode bands 1 and the three different anode bands 2R, 2G, 2B a two-dimensional mesh according to FIG. 1 was produced, in which the three anode bands 2 were used alternately, that is to say 2R, 2G, 2B, 2R, 2G, 2B, . . . as warp thread and the anode bands 2 as weft thread. The two-dimensional mesh obtained was provided with electrical connections and placed between two 1 mm thick glass plates, which were pressed together at temperatures of 80 C and sealed gas-tight by means of a thermosetting adhesive. A full-color, electroluminescent device was obtained.

### Example of Embodiment 7

Cathode bands 1 were produced by depositing a 5 nm thick layer of barium on a 200 μm thick aluminum foil. In this embodiment the aluminum foil functions as substrate 3 and as first layer of the first electrode 4. A 30 nm thick first organic layer 5 of Alq₃ was deposited on the layer of barium, and a second organic layer 6 of BAlq was deposited on the first organic layer 5. The coated polyamide film was then cut into 200 μm wide strips.

Anode bands 2 were also produced by depositing a 100 nm thick SiO₂-layer as additional layer 9 on a polyamide film as substrate 3. A 150 nm thick second electrode 7 of ITO was deposited on the additional layer 9. A 200 nm thick third organic layer 8 of PDOT was deposited on the second electrode 7. A 30 nm thick, fourth organic layer 10 of α-NPD was deposited on the third organic layer 8. A fifth organic layer of CBP doped with 5% Ir(ppy)₃ was applied to the fourth, organic layer 10.

From the cathode bands 1 and the anode bands 2 a two-dimensional mesh according to FIG. 1 was produced using the cathode bands 1 as weft thread and the anode bands 2 as warp thread. The two-dimensional mesh obtained was provided with electrical connections and placed between two 1 mm thick glass plates, which were then pressed together at temperatures of 80° C. and sealed gas-tight by means of a thermo-setting adhesive. An electroluminescent device was obtained, which emitted blue light at each second point of intersection.

### Example of Embodiment 8

Cathode bands 1 were produced by depositing a first electrode 4 comprising three layers on a polyamide film as substrate 3. The first layer, which adjoined the substrate 3, contained a 20 nm thick layer of ZnS, the second layer contained a 20 nm thick layer of Ag and the third layer contained a 10 nm thick layer of cesium-doped biphenyl. A first organic layer 5 of Alq₃ was applied to the first electrode 4. The layer thickness of the first organic layer 5, which functioned as electron-conducting layer, was 80 nm. The coated polyamide film was then cut into 200 μm wide strips.

Anode bands 2 were also produced by depositing a second electrode 7 comprising a 35 nm thick layer of α-NPD on a polyamide film as substrate 3. A 80 nm thick third organic layer 8 of 4,4′-bis(carbazole-9-yl)biphenyl (CBP) doped with 8% FIrpic was deposited on the second electrode 7. A 30 nm thick, fourth organic layer 10 of PBD was deposited on the third organic layer 8. The coated polyamide film was then cut into 250 μm wide strips.

From the cathode bands 1 and the anode bands 2 a two-dimensional mesh according to FIG. 1 was produced using the cathode bands 1 as weft thread and the anode bands 2 as warp thread. The two-dimensional mesh was provided with electrical connections and placed between two 1 mm thick glass plates, which were then pressed together at temperatures of 80° C. and sealed gas-tight by means of an adhesive, which was set by irradiation with UV light. An electroluminescent device was obtained, which emitted blue light at each second point of intersection.

1. An electroluminescent device, which comprises a first set of bands and a second set of bands, which are arranged in such a way, that they form a two-dimensional mesh with points of intersection between the bands of the first set and the bands of the second set, the bands in each case consisting of a sequence of layers and at least one set of bands containing a light-emitting substance, which emits light when a voltage is applied between the first set of bands and the second set of bands.

2. An electroluminescent device as claimed in claim 1, characterized in that the bands in each case contain an organic layer (5,6,8,10) and at the points of intersection the organic layer (5,6) of the first set of bands is in contact with the organic layer (8,10) of the second set of bands.

3. An electroluminescent device as claimed in claim 2, characterized in that the organic layer (5,6,8,10) is a material selected from the group of organic polymers, organic copolymers, organic oligomers, metal complexes having at least one organic ligand, heterocycles and amines.

4. An electroluminescent device as claimed in claim 1, characterized in that a band of the first set of bands has a substrate (3), a first electrode (4) adjoining the substrate (3) and a first organic layer (5) adjoining the first electrode (4).

5. An electroluminescent device as claimed in claim 4, characterized in that a second organic layer (6) adjoins the first organic layer (5).

6. An electroluminescent device as claimed in claim 4, characterized in that the first organic layer (5) and the second organic layer (6) contain an electron-conducting material or a light-emitting substance.

7. An electroluminescent device as claimed in claim 1, characterized in that a band of the second set of bands has a substrate (3), a second electrode (7) adjoining the substrate (3) and a third organic layer (8) adjoining the second electrode (7).

8. An electroluminescent device as claimed in claim 4, characterized in that a fourth organic layer (10) adjoins the third organic layer (8).

9. An electroluminescent device as claimed in claim 7, characterized in that the third organic layer (8) and the fourth organic layer (10) contain a hole-conducting material or a light-emitting substance.

10. An electroluminescent device as claimed in claim 7, characterized in that an additional layer (9) is situated between the substrate (3) and the second electrode (7).

11. An electroluminescent device as claimed in claim 10, characterized in that the additional layer (9) contains pigment or SiO₂.
